(19) United States
(12) Patent Application Publication
(10) Pub. No.: US 2009/0303796 A1
(43) Pub. Date: Dec. 10, 2009

(54) SEMICONDUCTOR MEMORY DEVICE

(75) Inventor: Takumi ABE, Mountain View, CA (US)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/413,065

(22) Filed: Mar. 27, 2009

(30) Foreign Application Priority Data
Jun. 4, 2008 (JP) 2008-146611

(51) Int. Cl. G11C 16/04; G11C 16/06; G11C 7/10

(52) U.S. Cl. 365/185.17; 365/185.21; 365/185.23; 365/189.06

(57) ABSTRACT

A semiconductor memory device including: a memory cell coupled to a bit line via a select gate transistor; a sense amplifier configured to have a current source for supplying current to the bit line, and detect cell current of the memory cell flowing on the bit line; and a select gate line driver configured to drive the select gate transistor so as to keep the memory cell applied with substantially constant drain-source voltage independently of the bit line resistance at a read time.

### CROSS-REFERENCE TO RELATED APPLICATION

This application is based on and claims the benefit of priority from the prior Japanese Patent Application No. 2008-146611, filed on Jun. 4, 2008, the entire contents of which are incorporated herein by reference.

### BACKGROUND OF THE INVENTION

1. Field of the Invention

This invention relates to a semiconductor memory device, specifically to a sense scheme of a highly integrated memory device.

2. Description of the Related Art

A NAND-type flash memory is well known as one of electrically rewritable and non-volatile semiconductor memories (EEPROMs). As a sense amplifier used in the NAND-type flash memory, it is known such a current-sensing type of sense amplifier as to detect cell current of a selected memory cell under the condition that the selected memory cell is applied with drain-source voltage of about 0.5V (refer to, for example, JP-A-2006-500727). In this sense scheme, the drain-source voltage of the selected memory cell is controlled with the gate voltage of a clamping transistor disposed near the bit line in the sense amplifier.

In a NAND-type flash memory, in which size-shrinking, integration and capacitance increase are progressing, the bit line becomes highly resistive, and it leads to difficulty of controlling the drain-source voltage of the memory cell due to the voltage drop of the bit line resistance. In practice, in the conventional sense scheme, the drain-source voltage applied to the memory cell becomes lower than the clamping voltage because the voltage drop due to the bit line resistance becomes large.

As the drain-source voltage of the memory cell is substantially lowered as described above, the cell current becomes less. Therefore, even if an erase cell is set in a sufficiently low threshold voltage state, there is a possibility of generating an erroneous read such that the erase cell is not detected as it is.

### SUMMARY OF THE INVENTION

According to an aspect of the present invention, there is provided a semiconductor memory device including:

a memory cell coupled to a bit line via a select gate transistor;

a sense amplifier configured to have a current source for supplying current to the bit line, and detect cell current of the memory cell flowing on the bit line; and

a select gate line driver configured to drive the select gate transistor so as to keep the memory cell applied with substantially constant drain-source voltage independently of the bit line resistance at a read time.

According to another aspect of the present invention, there is provided a semiconductor memory device including:

word lines and a select gate line disposed in parallel with each other;

a bit line disposed to cross the word lines and the select gate line;

a NAND string including multiple memory cells connected in series to the bit line via a select gate transistor, the control gates of the memory cells being coupled to the word lines, the gate of the select gate transistor being coupled to the select gate line;

word line drivers configured to selectively drive the word lines;

a select gate line driver configured to selectively drive the select gate line; and

a sense amplifier coupled to the bit line to detect cell current of a selected memory cell in the NAND string, wherein

the select gate transistor is NMOS transistor, and the select gate line driver is configured to drive the NMOS transistor so as to clamp the source voltage at a substantially constant level independently of the bit line resistance at a read time.

### BRIEF DESCRIPTION OF THE DRAWINGS

FIG. 1 shows a block configuration of a NAND-type flash memory in accordance with an embodiment.

FIG. 2 shows a memory cell array of the flash memory.

FIG. 3 shows a sense amplifier of the flash memory.

FIG. 4 shows a select gate line driver of the flash memory.

FIG. 5 shows a conventional read-use SGD voltage generator.

FIG. 6 shows a read-use SGD voltage generator in accordance with this embodiment.

FIG. 7 shows the voltage relationship from the sense amplifier to the NAND string in a conventional sense scheme.

FIG. 8 shows the operating point movement due to the bit line resistance in the conventional sense scheme.

FIG. 9 shows the voltage relationship from the sense amplifier to the NAND string in a sense scheme in accordance with this embodiment.

FIG. 10 shows the cell characteristic in a sense scheme in accordance with this embodiment.

FIG. 11 shows another read-use SGD voltage generator in accordance with his embodiment.

FIG. 12 shows another embodiment applied to a digital still camera.

FIG. 13 shows the internal configuration of the digital still camera.

FIGS. 14A to 14J show other electric devices to which the embodiment is applied.

### DETAILED DESCRIPTION OF THE EMBODIMENTS

Illustrative embodiments of this invention will be explained with reference to the accompanying drawings below.

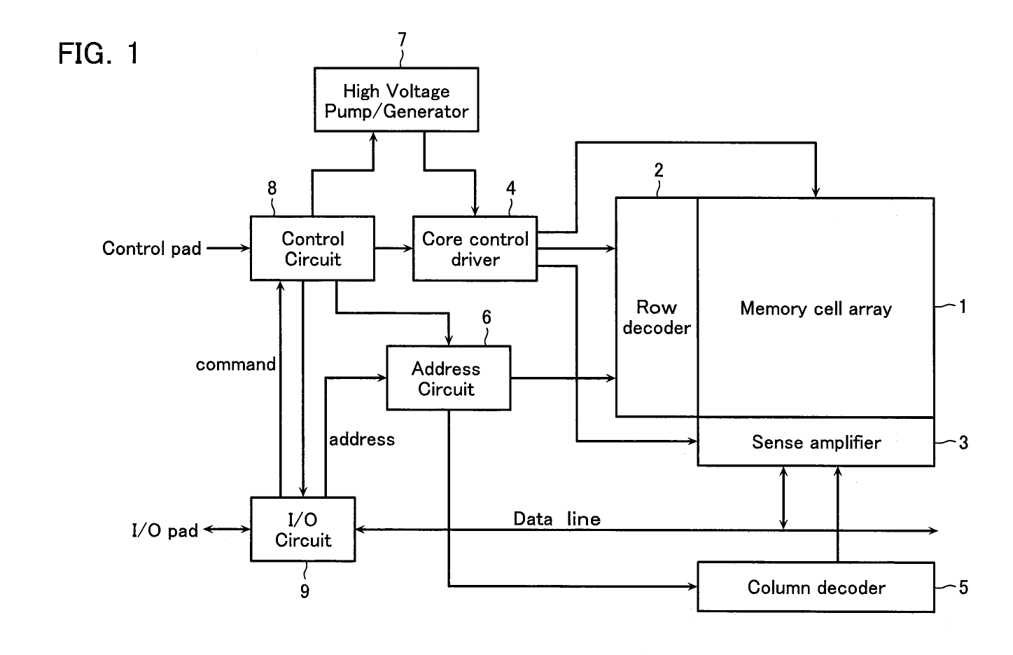

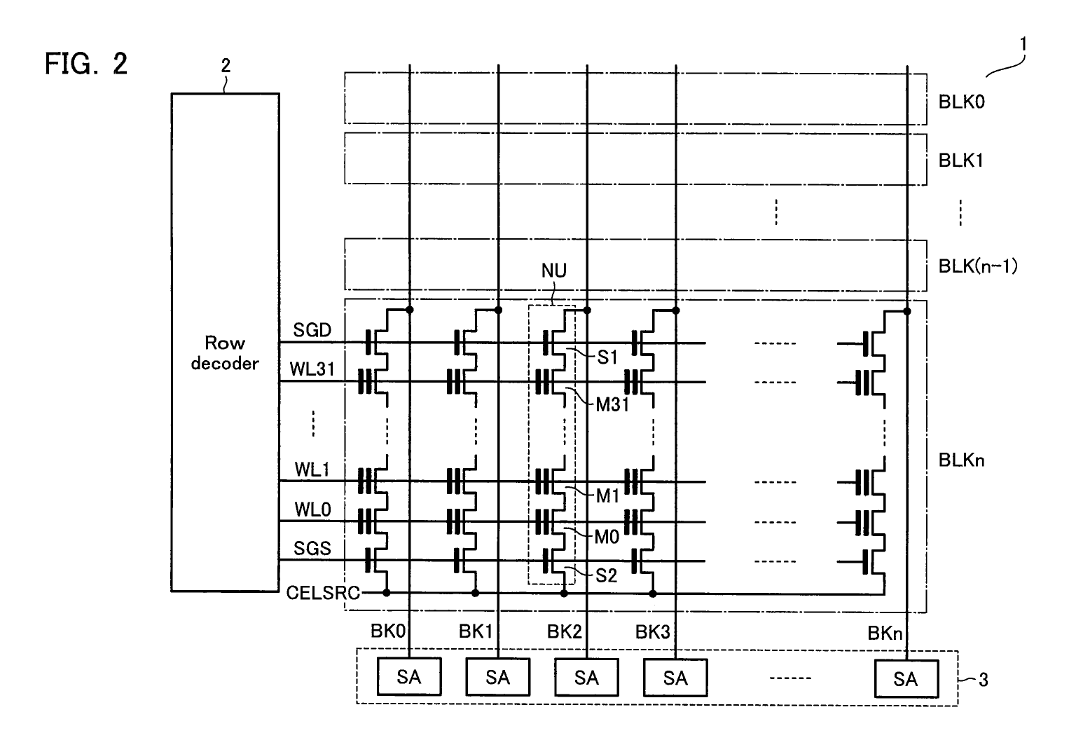

FIG. 1 shows a functional block configuration of a NAND-type flash memory in accordance with an embodiment, and FIG. 2 shows the memory core. Memory cell array 1 is, as shown in FIG. 2, formed of NAND cell units (NAND strings), NU, arranged therein, each of which has multiple memory cells M0-M31 connected in series.

The memory cell has a MOS transistor structure, in which a floating gate and a control gate are stacked, and stores data defined by a high threshold state obtained by injecting electrons into the floating gate and a low threshold state obtained by discharging electrons stored in the floating gate. Alternatively, it may be used another cell structure, in which a charge trap layer or boundary is formed in the gate insulating film, and the same data storage is done as that of the above-described floating gate type of memory cell.

One end of the NAND string NU is coupled to a bit line BL via a select gate transistor S1 while the other end is coupled to a common source line CELSRC via another select gate transistor S2. Control gates of memory cells M0-M31 are coupled to word lines WL0-WL31, respectively; and gates of select gate transistors S1 and S2 to select gate lines SGD and SGS, respectively.

To selectively drive word lines and select gate lines, row decoder 2 is disposed. Bit lines BL are coupled to sense amplifier circuit 3. In the example shown in FIG. 2, sense amplifier circuit 3 has one page of sense amplifiers SA, which are disposed for the respective bit lines BL. Alternatively, it is effective to use such a sense amplifier sharing scheme that adjacent two bit lines share a sense amplifier, and one selected bit line is coupled to the sense amplifier.

A set of memory cells selected simultaneously with a selected word line constitutes a page, which serves as a simultaneous-read or write unit. A set of NAND strings sharing word lines constitutes a block serving as an erase unit. As shown in FIG. 2, memory cell array 1 usually includes multiple blocks BLK0-BLKn arranged in the bit line direction.

One page read data read in the sense amplifier circuit 3 is transferred to data line column by column with column decoder 5, and output to I/O pads via I/O buffer 9. One page write data is input by a column to be loaded in the sense amplifier circuit 3.

Command input via I/O buffer 9 is decoded in controller 8, and serves for controlling operations. Address input via I/O buffer 9 is transferred to row decoder 2 and column decoder 5 via address register 6.

Controller 8 executes read, write and erase sequences in accordance with the command instructions and various external control signals (chip enable signal, command latch signal, address latch signal, write enable signal, read enable signal, and the like).

To generate high voltages required in the read, write and erase modes, there is prepared a high voltage generating circuit 7, which is controlled by the internal controller 8.

Core control driver 4 is prepared for generating voltages for driving word lines and select gate lines in a block selected by row decoder 2 under the control of controller 8.

FIG. 4 shows a part of core control driver 4, i.e., select gate line (SGD) driver 40. To drive the select gate line SGD in correspondence with operation modes, there are prepared SGD voltage generator 41a used in a read mode, SGD voltage generator 41b used in a fast program mode, SGD voltage generator 41c used in a slow program mode, SGD voltage generator 41d used in an erase mode and SGD voltage generator 41e used in an erase-verify mode.

Output voltage of these drivers 41a-41e are supplied to the select gate line SGD without voltage drops via transfer transistors M11a-M11e driven by the respective level shift circuits LS.

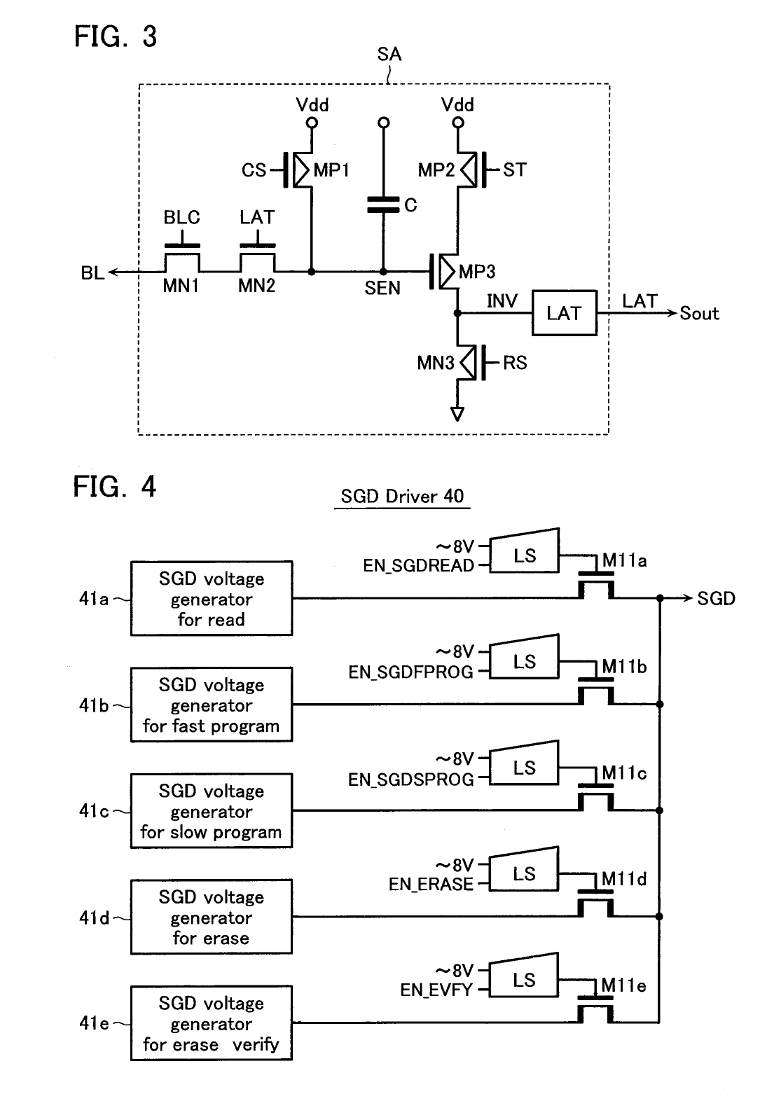

FIG. 3 shows a main portion of the sense amplifier SA. This is basically the same as shown in JP-A-2006-500727. This sense amplifier SA has a sense node SEN coupled to bit line BL via clamping NMOS transistor MN1 and bit line separating NMOS transistor MN2. Coupled to the sense node are capacitor C and precharging PMOS transistor MP1. Transistor MP1 is applied with gate voltage of 0V when turning on, and serves as a current source of about 500 nA.

Sense node SEN is coupled to the gate of sensing PMOS transistor MP3, the source of which is driven by power supply voltage Vdd via PMOS transistor MP2 driven by strobe signal ST at a sense time. Sensed output obtained at the drain of sensing PMOS transistor MP3 will be taken in latch LAT.

Coupled to the drain of PMOS transistor MP3 is resetting NMOS transistor MN3. The above-described bit line separating NMOS transistor MN2 is turned on or off in accordance with data stored in latch LAT. At a read time, NMOS transistor MN2 is on with LAT=“H”.

In a read mode, PMOS transistor MP1 is turned on, thereby charging up the sense node SEN to Vdd. On the other hand, in the NAND string, select gate transistors are turned on; a selected word line is applied with read voltage; and unselected word lines with read pass voltage, which turns on cells without regard to cell data. Bit line voltage in this read mode is defined with about the gate control voltage BLC of NMOS transistor MN1.

Then, precharge PMOS transistor MP1 is turned off. As a result, the sense node SEN is discharged in accordance with selected cell's data. In case of “0” data, i.e., the selected cell is off (“0”-cell), the sense node SEN is little discharged while in case of “1” date, i.e., the selected cell is on (“1”-cell), the sense node SEN will be discharged and lowered in level.

Turn on PMOS transistor MP2 with strobe pulse ST after a certain time, and the on/off state of PMOS transistor MP2 is determined in correspondence with the level of sense node SEN, which is determined in correspondence with cell current. The drain voltage of PMOS transistor MP2 is taken in latch LAT as read data.

The above description is the basic configuration and operation of the sense amplifier SA. It should be noted here that the setting method of the gate control voltage BLC of clamping NMOS transistor MN1 is different from that in a conventional method. That is, at a sense time, this transistor MN1 is not used as a bit line clamping one. This point will be explained in detail in comparison with the conventional sense scheme.

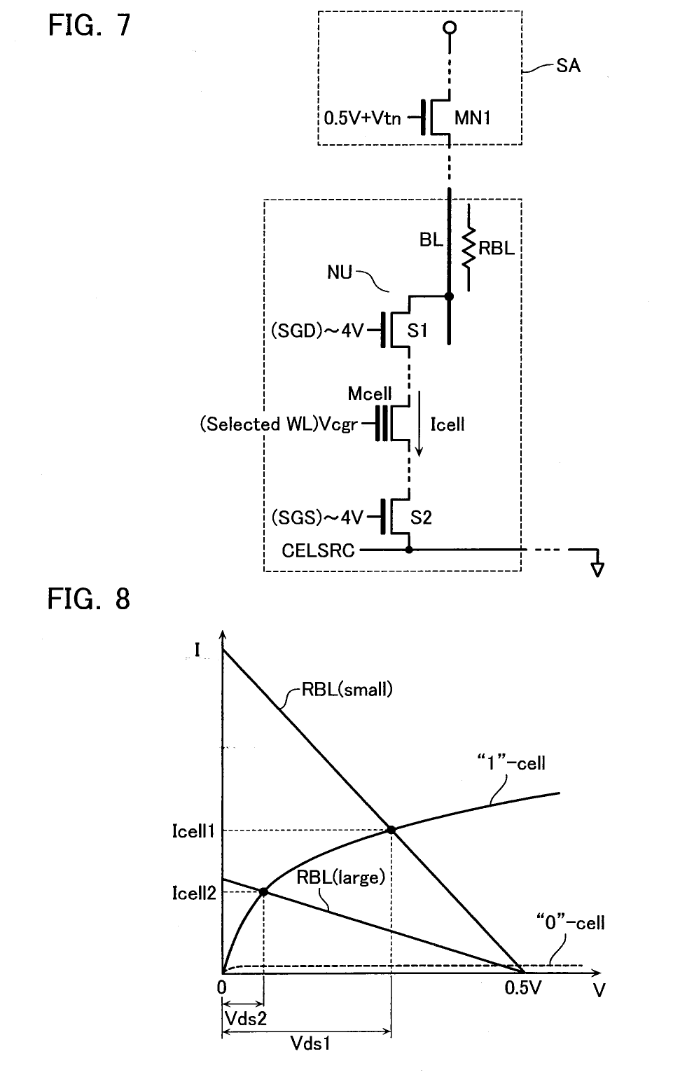

FIG. 7 shows voltages at the respective nodes in a range from the clamping transistor MN1 in the sense amplifier SA to the selected NAND string NU in the memory cell array 1. As described above, drain-source voltage of the selected cell Mcell is indirectly controlled based on that sense amplifier SA controls bit line voltage. Explaining in detail, the gate of clamp-use transistor MN1 is set at 0.5V+Vtn (Vtn: threshold voltage of MN1), and bit line voltage is clamped at 0.5V.

In the selected NAND string, gates of bit line side select gate transistor S2 and source line side select gate transistor S2 (i.e., select gate lines SGD and SGS) are applied with voltage (about 4V) set to be able to sufficiently turn on transistors, and the select word line is applied with read voltage Vcgr. Although, read voltage Vcgr in a normal read mode is different from that in a program-verify read mode, it will be set at a suitable level necessary for judging on/off of the selected cell. Unselected word lines in the selected NAND string are applied with read pass voltage Vread, which sets the unselected cells in a sufficiently low resistance on-state.

FIG. 8 shows the voltage-current characteristic and the operating point of the selected cell Mcell with solid lines, in case it is a “1”-cell, under the above described bias condition. There are shown two load lines, RBL(small) and RBL(large). The former is a case that the bit line resistance is small while the latter is another case that the bit line resistance is large. That is, this designates that under the above described bias condition, bit line resistance RBL appears as the load resistance of the selected cell.

In case the bit line resistance RBL is small, drain-source voltage is Vds1 while cell current is Icell1. This shows that the cell transistor is in a current saturation region. By contrast, in case the bit line resistance RBL is large, drain-source voltage is Vds2 (<Vds1) while cell current is Icell2 (<Icell1). That is, the cell current is largely suppressed with the bit line resistance RBL, and it leads to erroneous read.

Explaining in detail more, even if the selected cell Mcell is a sufficiently erased “1”-cell with a negative threshold voltage, the drain-source voltage of the selected cell Mcell becomes substantially low due to the bit line resistance RBL, and cell current becomes less. Therefore, it is a possibility that the “1” cell is erroneously read as a “0” cell (written in a positive threshold voltage state) shown by a dotted line in FIG. 8.

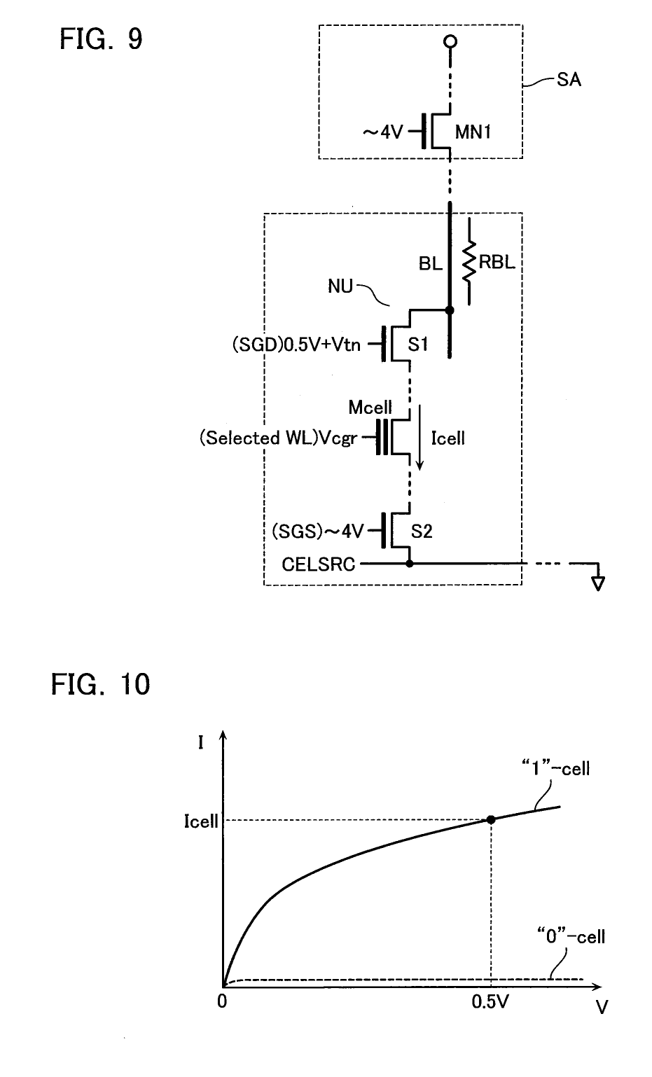

In contrast to the above description, FIG. 9 shows voltages at the respective nodes from the clamping transistor MN1 in the sense amplifier SA to the selected NAND string NU in the memory cell array 1, in accordance with the sense scheme used in this embodiment. In this embodiment, the gate of clamping transistor MN1 in the sense amplifier SA is set at a voltage sufficiently turning on it, for example, about 4V, while the gate of the bit line side select gate transistor S1 in the selected NAND string is set at 0.5V+Vtn (Vtn: threshold voltage of the select gate transistor).

With this bias relationship, clamping NMOS transistor MN1 is deeply turned on, and does not clamp the bit line voltage as different from the case shown in FIG. 7. Further, in case the drain voltage of the select gate transistor S1 is over 0.5V, it does not influence the operating point of the selected cell Mcell even if the drain voltage is slightly varied in accordance with the bit line resistance RBL. That is, the bit line resistance RBL does not appear as a load resistance of the selected cell, and source voltage of the select gate transistor S1 is clamped at 0.5V, so that about constant drain voltage is applied to the selected cell Mcell without regard to the bit line resistance value.

Therefore, the characteristic and the operating point of the selected cell are shown by a solid line in FIG. 10. The drain-source voltage of the selected cell is substantially constant (Vds=0.5V) independently from the bit line resistance RBL, and cell current thereof Icell becomes sufficiently large and about constant in a saturation region. As a result, it becomes possible to avoid the erroneous read due to the bit line resistance RBL. Erroneous judgment in a program-verify mode may also be avoided due to the same reason as described above.

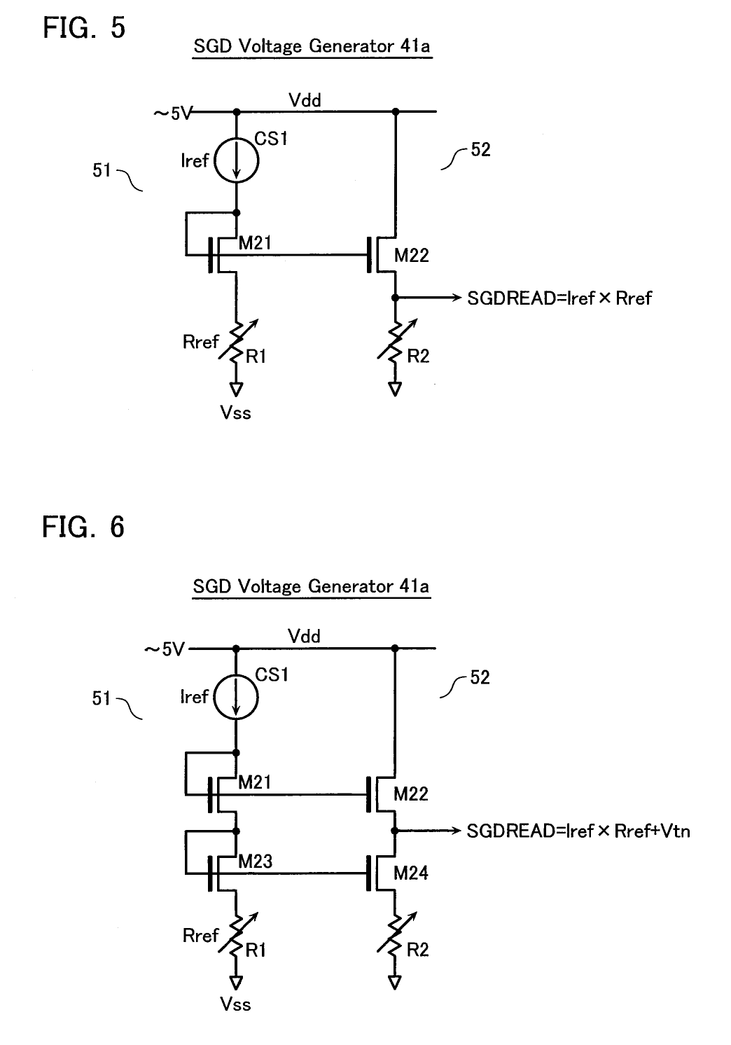

To make the above-described sense scheme possible, it is required of the SGD voltage generating circuit 41a shown in FIG. 4 to be improved. This point will be explained below with reference to FIGS. 5 and 6.

FIG. 5 shows a SGD voltage generator 41a in the read mode, which is usually used. Between the power supply voltage node Vdd (about 5V) and the ground potential node Vss, basic current source CS1 (base current Iref), diode-connected NMOS transistor M21 and basic resistance element R1 (base resistance Rref) are coupled in series to constitute a basic voltage generating circuit 51, which generates base voltage Iref×Rref.

Disposed to output the base voltage is voltage output circuit 52, which has NMOS transistor M22 and resistance element R2 connected in series between Vdd and Vss to constitute a source follower circuit. NMOS transistor M22 constitutes a current mirror circuit together with NMOS transistor M21.

The resistance value ratio of element R1 to element R2 is set at the same value as the ratio of channel length L to channel width W of NMOS transistors M21 and M22. For example, in case transistors M21 and M22 have the same size, resistances R1 and R2 are set to have the same resistance value. With this configuration, the base voltage Iref×Rref becomes the output voltage, which is supplied to the gate of the select gate transistor S1. For example, in the bias relationship shown in FIG. 7, Iref×Rref is set to be 4V.

By contrast with this, FIG. 6 shows a SGD voltage generator 41a in the read mode in accordance with this embodiment. What is different from that shown in FIG. 5 is that two diode-connected NMOS transistors M21 and M23 are inserted in series between current source CS1 and resistance R1 in the basic voltage generating circuit 51. Further, in the voltage output circuit 52, two NMOS transistors M22 and M24 are inserted in correspondence to NMOS transistors M21 and M23, and the connection node of NMOS transistors M22 and M24 serves as the voltage output node.

NMOS transistors M21 and M22 have a common gate; and NMOS transistors M23 and M24 have another common gate.

With this configuration, there is generated output voltage expressed by Iref×Rref+Vtn (Vtn; threshold voltage of NMOS transistor). For example, assuming that Iref=10 μA and Rref=50 kΩ, the obtained output voltage is 0.5V+Vtn. More precisely expressing this voltage with β value of NMOS transistor M24, it becomes as follows: Iref×Rref+Vtn+(2Iref/β)^{1/2}.

In practice, the drain-source voltage of the selected memory cell is variably controllable with the base current Iref and base resistance Rref, and settable at an optimum value in correspondence to the cell property. Since the threshold voltage Vtn is varied dependently on temperature, it is required of transistors M23 and M24 to have as similar property as that of the select gate transistor S1 in the core as possible. For example, transistors M23 and M24 are selected to have the same size as that of the select gate transistor.

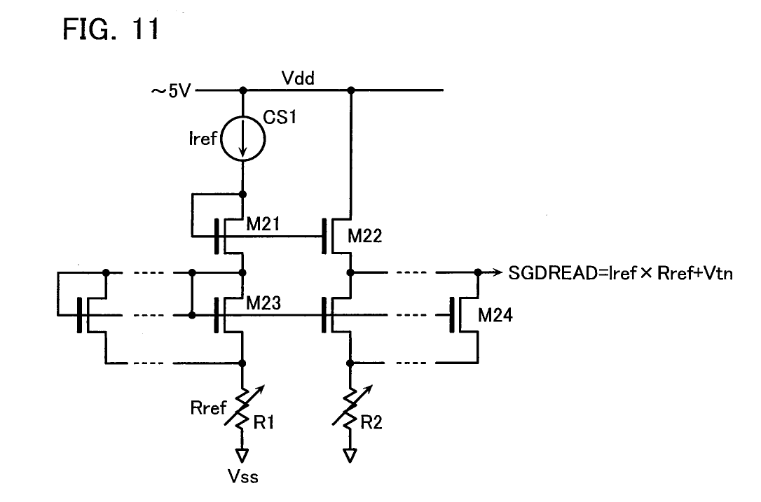

If it is required of these transistors M23 and M24 to have large gate width W, as shown in FIG. 11, these transistors may be formed of parallel-connected transistors. Make one of the parallel-connected transistors have the same size as the select gate transistor, and transistors M23 and M24 have substantially the same property as the select gate transistor and a larger gate width than that of the select gate transistor.

As an embodiment, an electric card using the non-volatile semiconductor memory devices according to the above-described embodiment of the present invention and an electric device using the card will be described bellow.

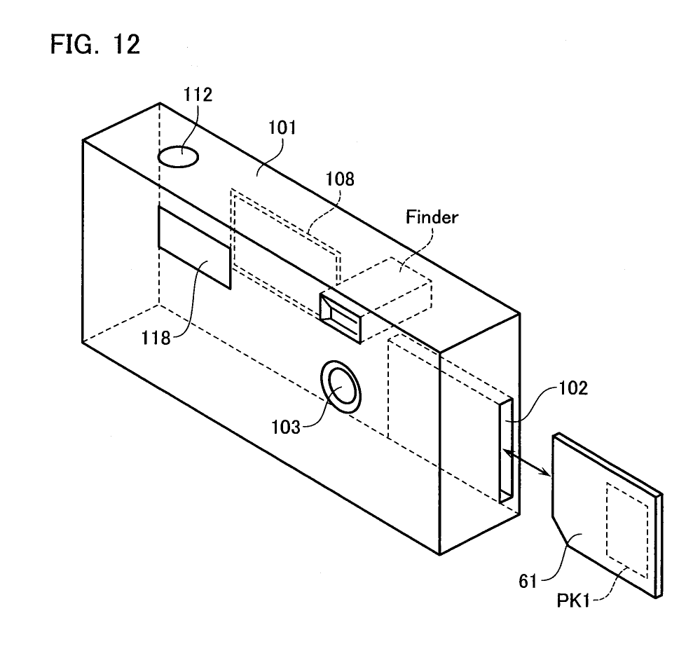

FIG. 12 shows an electric card according to this embodiment and an arrangement of an electric device using this card. This electric device is a digital still camera 101 as an example of portable electric devices. The electric card is a memory card 61 used as a recording medium of the digital still camera 101. The memory card 61 incorporates an IC package PK1 in which the non-volatile semiconductor memory device or the memory system according to the above-described embodiments is integrated or encapsulated.

The case of the digital still camera 101 accommodates a card slot 102 and a circuit board (not shown) connected to this card slot 102. The memory card 61 is detachably inserted in the card slot 102 of the digital still camera 101. When inserted in the slot 102, the memory card 61 is electrically connected to electric circuits of the circuit board.

If this electric card is a non-contact type IC card, it is electrically connected to the electric circuits on the circuit board by radio signals when inserted in or approached to the card slot 102.

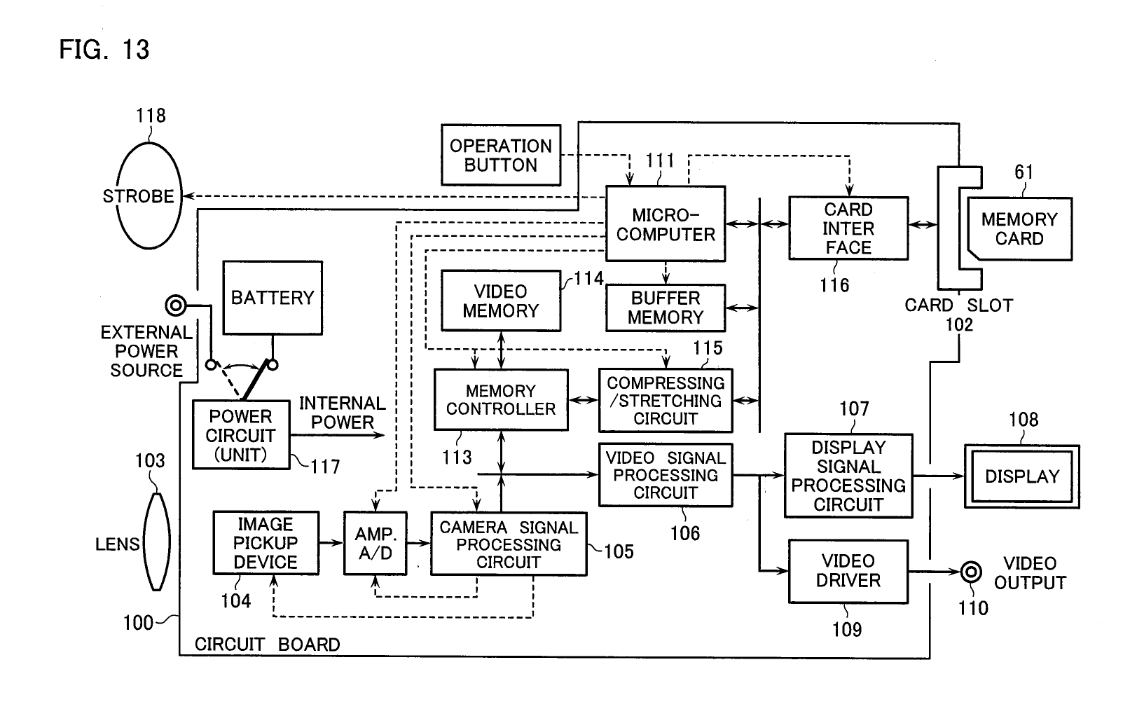

FIG. 13 shows a basic arrangement of the digital still camera. Light from an object is converged by a lens 103 and input to an image pickup device 104. The image pickup device 104 is, for example, a CMOS sensor and photoelectrically converts the input light to output, for example, an analog signal. This analog signal is amplified by an analog amplifier (AMP), and converted into a digital signal by an A/D converter (A/D). The converted signal is input to a camera signal processing circuit 105 where the signal is subjected to automatic exposure control (AE), automatic white balance control (AWB), color separation, and the like, and converted into a luminance signal and color difference signals.

To monitor the image, the output signal from the camera processing circuit 105 is input to a video signal processing circuit 106 and converted into a video signal. The system of the video signal is, e.g., NTSC (National Television System Committee). The video signal is input to a display 108 attached to the digital still camera 101 via a display signal processing circuit 107. The display 108 is, e.g., a liquid crystal monitor.

The video signal is supplied to a video output terminal 110 via a video driver 109. An image picked up by the digital still camera 101 can be output to an image apparatus such as a television set via the video output terminal 110. This allows the pickup image to be displayed on an image apparatus other than the display 108. A microcomputer 111 controls the image pickup device 104, analog amplifier (AMP), A/D converter (A/D), and camera signal processing circuit 105.

To capture an image, an operator presses an operation button such as a shutter button 112. In response to this, the microcomputer 111 controls a memory controller 113 to write the output signal from the camera signal processing circuit 105 into a video memory 114 as a flame image. The flame image written in the video memory 114 is compressed on the basis of a predetermined compression format by a compressing/stretching circuit 115. The compressed image is recorded, via a card interface 116, on the memory card 61 inserted in the card slot.

To reproduce a recorded image, an image recorded on the memory card 61 is read out via the card interface 116, stretched by the compressing/stretching circuit 115, and written into the video memory 114. The written image is input to the video signal processing circuit 106 and displayed on the display 108 or another image apparatus in the same manner as when image is monitored.

In this arrangement, mounted on the circuit board 100 are the card slot 102, image pickup device 104, analog amplifier (AMP), A/D converter (A/D), camera signal processing circuit 105, video signal processing circuit 106, display signal processing circuit 107, video driver 109, microcomputer 111, memory controller 113, video memory 114, compressing/stretching circuit 115, and card interface 116.

The card slot 102 need not be mounted on the circuit board 100, and can also be connected to the circuit board 100 by a connector cable or the like.

A power circuit 117 is also mounted on the circuit board 100. The power circuit 117 receives power from an external power source or battery and generates an internal power source voltage used inside the digital still camera 101. For example, a DC-DC converter can be used as the power circuit 117. The internal power source voltage is supplied to the respective circuits described above, and to a strobe 118 and the display 108.

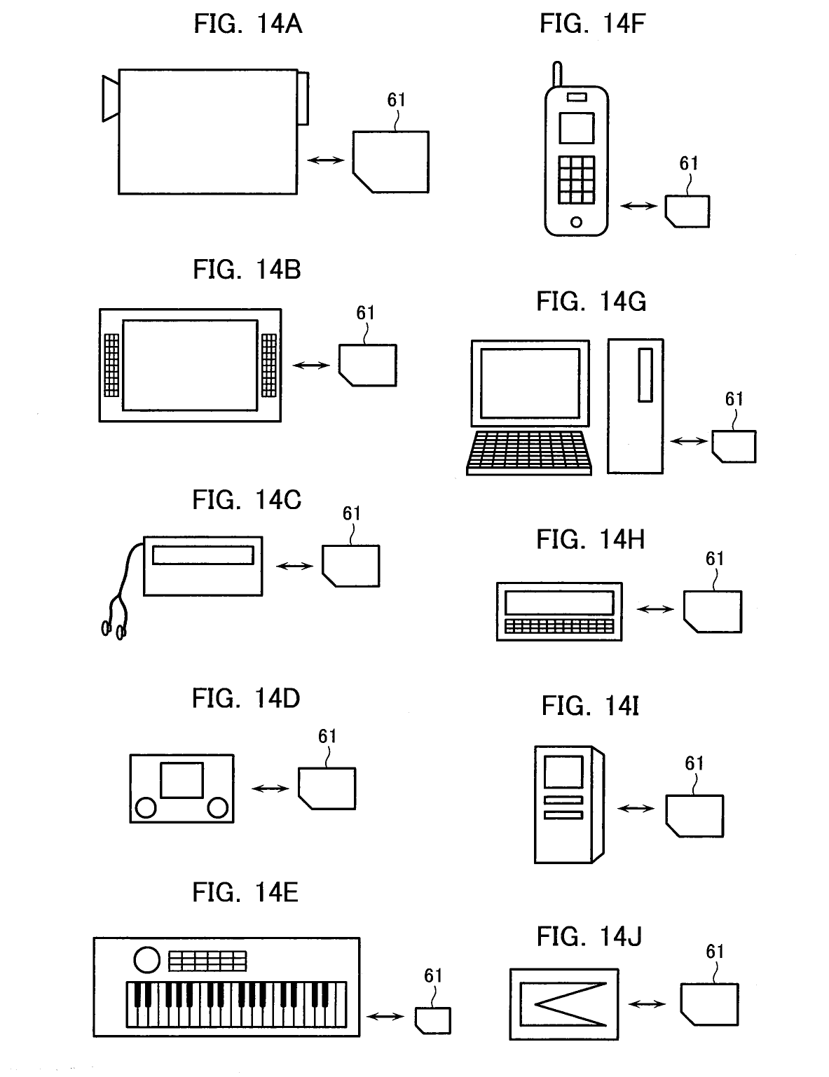

As described above, the electric card according to this embodiment can be used in portable electric devices such as the digital still camera explained above. However, the electric card can also be used in various apparatus such as shown in FIGS. 14A to 14J, as well as in portable electric devices. That is, the electric card can also be used in a video camera shown in FIG. 14A, a television set shown in FIG. 14B, an audio apparatus shown in FIG. 14C, a game apparatus shown in FIG. 14D, an electric musical instrument shown in FIG. 14E, a cell phone shown in FIG. 14F, a personal computer shown in FIG. 14G, a personal digital assistant (PDA) shown in FIG. 14H, a voice recorder shown in FIG. 14I, and a PC card shown in FIG. 14J.

This invention is not limited to the above-described embodiment. It will be understood by those skilled in the art that various changes in form and detail may be made without departing from the spirit, scope, and teaching of the invention.

What is claimed is:

1. A semiconductor memory device comprising:
a memory cell coupled to a bit line via a select gate transistor;
a sense amplifier configured to have a current source for supplying current to the bit line, and detect cell current of the memory cell flowing on the bit line; and
a select gate line driver configured to drive the select gate transistor so as to keep the memory cell applied with substantially constant drain-source voltage independently of the bit line resistance at a read time.

2. The semiconductor memory device according to claim 1, wherein
a plurality of the memory cells connected in series constitutes a NAND string, one end of which is coupled to the bit line via the select gate transistor.

3. The semiconductor memory device according to claim 1, wherein
the select gate driver comprises:
a basic voltage generator having a basic current source, first and second diode-connected NMOS transistors, and a first resistance element connected in series between a power supply node and a ground potential node; and
a voltage output circuit having third and fourth NMOS transistors, the gates of which are coupled to those of the first and second NMOS transistors, respectively, and a second resistance element connected in series between the power supply node and the ground potential node, the connection node between the third and fourth NMOS transistors serving as an voltage output node to be coupled to the gate of the select gate transistor.

4. The semiconductor memory device according to claim 3, wherein
the ratio of the channel length/channel width of the first NMOS transistor to that of the third NMOS transistor is set at the same as the resistance value ratio of the first resistance element to the second resistance element.

5. The semiconductor memory device according to claim 3, wherein
the second and fourth NMOS transistors each formed of multiple parallel-connected transistors with the same size as the select gate transistor.

6. The semiconductor memory device according to claim 1, wherein
the sense amplifier comprises:
a sensing PMOS transistor, the gate of which serves as a sense node, the source being coupled to the power supply node at a sense time;
a current-supplying PMOS transistor and a capacitor coupled to the sense node for serving as the current source;
a clamping NMOS transistor disposed between the sense node and the bit line; and
a latch coupled to the drain of the sensing PMOS transistor to take in sensed data, wherein
at the read time, the clamping NMOS transistor is set in such a deep on-state that the bit line voltage is not clamped.

7. The semiconductor memory device according to claim 6, wherein
the sense amplifier further comprises:
a bit line separating NMOS transistor disposed between the sense node and the clamping NMOS transistor to be driven in accordance with data stored in the latch in a write mode.

8. A semiconductor memory device comprising:
word lines and a select gate line disposed in parallel with each other;
a bit line disposed to cross the word lines and the select gate line;
a NAND string including multiple memory cells connected in series to the bit line via a select gate transistor, the control gates of the memory cells being coupled to the word lines, the gate of the select gate transistor being coupled to the select gate line;
word line drivers configured to selectively drive the word lines;
a select gate line driver configured to selectively drive the select gate line; and
a sense amplifier coupled to the bit line to detect cell current of a selected memory cell in the NAND string, wherein
the select gate transistor is NMOS transistor, and the select gate line driver is configured to drive the NMOS transistor so as to clamp the source voltage at a substantially constant level independently of the bit line resistance at a read time.

9. The semiconductor memory device according to claim 8, wherein
the sense amplifier comprises:
a sensing PMOS transistor, the gate of which serves as a sense node, the source being coupled to the power supply node at a sense time;
a current-supplying PMOS transistor and a capacitor coupled to the sense node for serving as the current source;
a clamping NMOS transistor disposed between the sense node and the bit line; and
a latch coupled to the drain of the sensing PMOS transistor to take in sensed data, wherein
at the read time, the clamping NMOS transistor is set in such a deep on-state that the bit line voltage is clamped.

10. The semiconductor memory device according to claim 8, wherein
the select gate line driver comprises:
a basic voltage generator having basic current source, first and second diode-connected NMOS transistors, and a first resistance element connected in series between a power supply node and a ground potential node; and
a voltage output circuit having third and fourth NMOS transistors, the gates of which are coupled to those of the first and second NMOS transistors, respectively, and a second resistance element connected in series between the power supply node and the ground potential node, the connection node between the third and fourth NMOS transistors serving as an voltage output node to be coupled to the gate of the select gate transistor.

11. The semiconductor memory device according to claim 10, wherein
the ratio of the channel length/channel width of the first NMOS transistor to that of the third NMOS transistor is set at the same as the resistance value ratio of the first resistance element to the second resistance element.

12. The semiconductor memory device according to claim 10, wherein
the second and fourth NMOS transistors each formed of multiple parallel-connected transistors with the same size as the select gate transistor.

13. The semiconductor memory device according to claim 9, wherein
the sense amplifier further comprises:
a bit line separating NMOS transistor disposed between the sense node and the clamping NMOS transistor to be driven in accordance with data stored in the latch in a write mode.
